(19) United States
(12) Patent Application Publication
(10) Pub. No.: US 2012/0295417 A1
(43) Pub. Date: Nov. 22, 2012

(54) SELECTIVE EPITAXIAL GROWTH BY INCUBATION TIME ENGINEERING

(75) Inventors: Thomas N. Adam, Slingerlands, NY (US); Katherina E. Babich, Chappaqua, NY (US); Stephen W. Bedell, Wappingers Falls, NY (US); Joel P. de Souza, Putnam Valley, NY (US); Gerald W. Gibson, Danbury, CT (US); Alexander Reznicek, Mount Kisco, NY (US); Devendra K. Sadana, Pleasantville, NY (US); Seshadri Subbanna, Brewster, NY (US)

(73) Assignee: INTERNATIONAL BUSINESS MACHINES CORPORATION, Armonk, NY (US)

(21) Appl. No.: 13/109,567

(22) Filed: May 17, 2011

(51) Int. Cl. H01L 21/20

(52) U.S. Cl. 438/478; 257/E21.09

(57) ABSTRACT

A method of controlling the nucleation rate (i.e., incubation time) of dissimilar materials in an epitaxial growth chamber that can favor high growth rates and can be compatible with low temperature growth is provided. The nucleation rate of dissimilar materials is controlled in an epitaxial growth chamber by altering the nucleation rate for the growth of a given material film, relative to single crystal growth of the same material film, by choosing an appropriate masking material with a given native nucleation characteristic, or by modifying the surface of the masking layer to achieve the appropriate nucleation characteristic. Alternatively, nucleation rate control can be achieved by modifying the surface of selected areas of a semiconductor substrate relative to other areas in which an epitaxial semiconductor material will be subsequently formed.

### BACKGROUND

The present disclosure relates to semiconductor processing and, more particular, to selective epitaxial growth of a semiconductor material using an incubation time engineered process.

Selective epitaxial crystal growth has become a performance enabling technology in modern complementary metal oxide semiconductor (CMOS) integrated circuit (IC) manufacturing. Example applications of this technique include, but are not limited to, embedded silicon germanium (SiGe) layers in transistor source and drain (S/D) regions to provide stress in the channel region, raised S/D regions to lower parasitic external resistance, and even to provide multiple crystal orientations on a single substrate.

Classical selective epitaxy uses an etchant gas such as HCl or chlorine in the process gas mixture, to suppress the nucleation of growth on a dielectric material or to etch away any amorphous or polycrystalline material (nuclei) deposited on the dielectric surface space. The result is that growth from the surface of a single crystal occurs, albeit at a lower growth rate than non-selective growth, but material growth from non-crystalline masking layers such as, for example, an oxide or a nitride, is inhibited.

One of the limitations of selective epitaxial growth techniques is the relatively high temperatures (greater than 650° C.) required for HCl to have an appreciable etch rate during growth. An example of this shortcoming is the challenge associated with growing carbon-doped silicon (Si:C), selectively, with a high substitutional C content of greater than 1 atomic percent. These Si:C layers are desired for use as embedded S/D layers which can provide uniaxial tensile stress for n-type field effect transistor (i.e., nFET) channel regions.

Such high substitutional C content is metastable and thus the layers need to be grown under non-equilibrium conditions; generally fast growth rates and low temperature growth, favor high substitutionality. These conditions are opposite to those provided by standard selective epitaxial growth techniques.

### SUMMARY

The present disclosure provides a method of controlling the nucleation rate (i.e., incubation time) of dissimilar materials in an epitaxial growth chamber. In one embodiment, the method of the present disclosure controls the nucleation rate (i.e., incubation time) of dissimilar materials in an epitaxial growth chamber that favors high growth rates (greater than 100 °/min) and is compatible with low temperature (less than 650° C.) growth.

In the present disclosure, the nucleation rate (i.e., incubation time) of dissimilar materials is controlled in an epitaxial growth chamber by altering the nucleation rate for the growth of a given material film, relative to single crystal growth of the same material film. In one embodiment, this can be achieved by choosing an appropriate masking material with a given native nucleation characteristic, or by modifying the surface of the masking layer to achieve the appropriate nucleation characteristic. In another embodiment, the above can be achieved by modifying the surface of selected areas of the substrate.

The advantages of the aforementioned approach are several fold: non-selective processes can be made to be partially or fully selective therefore growth rates are naturally higher (as the use of etching gases is obviated), low temperature selective growth can be permitted, and non-selective processes are inherently more manufacturable due to the reduced effects of complicated gas-phase equilibrium reactions giving rise to patterned dependent film properties.

In one aspect of the present disclosure, a method of forming a semiconductor material on selected areas of a semiconductor substrate is provided. The method includes forming a patterned masking material layer on selected areas of a semiconductor substrate, while leaving other selected areas of the semiconductor substrate exposed, wherein the patterned masking material layer has a slower nucleation rate for semiconductor growth than the exposed areas of the semiconductor substrate. The method further includes epitaxially growing a semiconductor material on the exposed areas of the semiconductor substrate not including the patterned masking material layer. The method further includes removing the patterned masking material layer selective to the epitaxially grown semiconductor material.

In another aspect of the present disclosure, another method of forming a semiconductor material on selected areas of a semiconductor substrate is provided. The method includes forming a modified surface region in selected areas of a semiconductor substrate, while leaving other selected areas of the semiconductor substrate non-modified, wherein the modified surface region has a slower nucleation rate for semiconductor growth than the non-modified areas of the semiconductor substrate. The method further includes epitaxially growing a semiconductor material on the non-modified areas of the semiconductor substrate not including the modified surface region.

### BRIEF DESCRIPTION OF THE DRAWINGS

FIG. 1 is a pictorial representation (through a cross-sectional view) depicting a semiconductor substrate that can be employed in one embodiment of the present disclosure.

FIG. 2 is a pictorial representation (through a cross-sectional view) depicting the semiconductor substrate of FIG. 1 after forming at least one patterned gate structure on an upper surface of the semiconductor substrate.

FIG. 3 is a pictorial representation (through a cross-sectional view) depicting the structure of FIG. 2 after forming a patterned masking material layer on areas of an upper surface of the semiconductor substrate and on sidewalls and atop the at least one patterned gate structure.

FIG. 4 is a pictorial representation (through a cross-sectional view) depicting the structure of FIG. 3 after selective epitaxial growth of a semiconductor material on areas of the semiconductor substrate that are exposed.

FIG. 5 is a pictorial representation (through a cross sectional view) depicting the structure of FIG. 4 after selectively etching the patterned masking material layer from the structure.

FIG. 6 is a pictorial representation (through a cross sectional view) depicting the structure of FIG. 2 after performing a surface treatment which forms modified surface regions within the initial semiconductor substrate in accordance with another embodiment of the present disclosure.

FIG. 7 is a pictorial representation (through a cross sectional view) depicting the structure of FIG. 6 after selective epitaxial growth of a semiconductor material on areas of the semiconductor substrate not including the modified surface regions.

### DETAILED DESCRIPTION

The present disclosure, which provides a method of controlling the nucleation rate of dissimilar materials in an epitaxial growth chamber which may favor high growth rates and can be compatible with low temperature growth, will now be described in greater detail by referring to the following discussion and drawings that accompany the present application. It is noted that the drawings are provided for illustrative purposes only and are not drawn to scale.

In the following description, numerous specific details are set forth, such as particular structures, components, materials, dimensions, processing steps and techniques, in order to illustrate the present disclosure. However, it will be appreciated by one of ordinary skill in the art that various embodiments of the present disclosure may be practiced without these, or with other, specific details. In other instances, well-known structures or processing steps have not been described in detail in order to avoid obscuring the various embodiments of the present disclosure.

It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

As stated above, the present disclosure provides a method of controlling the nucleation rate of dissimilar materials in an epitaxial growth chamber which may favor high growth rates and can be compatible with low temperature growth. In one embodiment, the aforementioned is achieved in the present disclosure by altering the nucleation rate for the growth of a given material film, relative to single crystal growth of the same material film, by choosing an appropriate masking material with a given native nucleation characteristic, or by modifying the surface of the masking layer to achieve the appropriate nucleation characteristic. In another embodiment, the aforementioned is achieved by modifying the surface of selected areas of the substrate.

The term “nucleation rate” is used throughout the present disclosure to denote the speed at which epi semiconductor material nuclei begins to form on a surface of a semiconductor substrate. The term “nucleation rate” can also be referred to as the “incubation time”. In the present disclosure, the epi semiconductor material nuclei forms faster on the exposed surface of the substrate as compared to either the patterned masking material layer that is formed on an upper surface of the substrate or modified surface regions that are formed in the substrate. As such, the methods disclosed in the present disclosure are capable of selectively growing an epitaxial (epi) semiconductor material on predetermined areas of a semiconductor substrate. The ‘selectivity’ can be achieved without utilizing an etchant gas such as HCl during the epitaxial growth process.

Although the various drawings of the present disclosure illustrate the formation of the epitaxially grown semiconductor material on a non-recessed, i.e., non-etched, surface of a semiconductor substrate, the present disclosure can also be employed in epitaxially growing a semiconductor material within a trench or opening that is formed into a semiconductor substrate. In some embodiments, a first trench or first opening is formed at the footprint of a patterned gate structure and on one side of the patterned gate structure, while a second trench or second opening is formed at the footprint of the patterned gate structure and on the other side of the patterned gate structure not including the first trench or first opening.

In one embodiment, the trench or opening can have substantially straight sidewalls. In another embodiment, the trench or opening can have slanted sidewalls. By “slanted wall profile” it is meant the surface of the wall created is oriented at a particular angle (relative to the top surface of the substrate) dictated by the crystallographic planes particular to crystallographic etchants and etch rate chosen. The ‘slant’ of the sidewall may be positive sloped, negative sloped, or a combination of both.

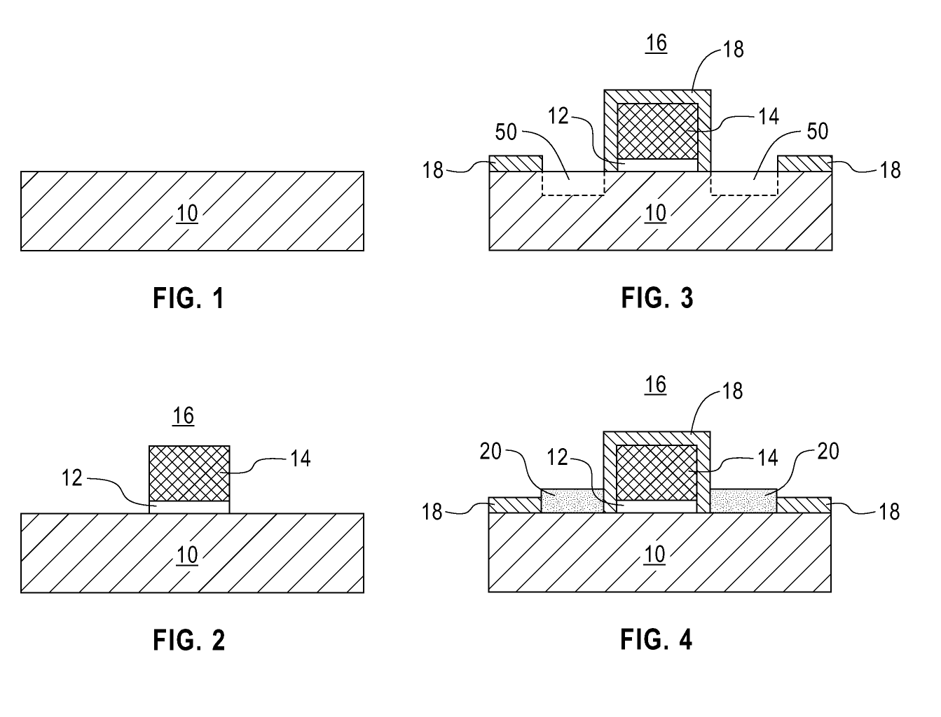

FIGS. 1-5 illustrate the basic processing steps that can be used in one embodiment of the present disclosure to control the nucleation of two dissimilar materials in an epitaxial growth reactor. Specifically, FIG. 1 illustrates a semiconductor substrate 10 that can be employed in one embodiment of the present disclosure. The semiconductor substrate 10 that can be employed in the present disclosure may include a bulk substrate, a semiconductor-on-insulator (SOI) substrate, or a hybrid orientation semiconductor substrate.

When a bulk semiconductor substrate is employed as semiconductor substrate 10, the bulk semiconductor substrate is comprised of any semiconductor material including, but not limited to, Si, Ge, SiGe, SiC, SiGeC, InAs, GaAs, InP or other like III/V compound semiconductors. Multilayers of these semiconductor materials can also be used as the semiconductor material of the bulk semiconductor. In one embodiment, the bulk semiconductor substrate is comprised of Si.

When an SOI substrate is employed as semiconductor substrate 10, the SOI substrate includes a handle substrate, a buried insulating layer located on an upper surface of the handle substrate, and a semiconductor layer located on an upper surface of the buried insulating layer. The handle substrate and the semiconductor layer of the SOI substrate may comprise the same, or different, semiconductor material. The term “semiconductor” as used herein in connection with the semiconductor material of the handle substrate and the semiconductor layer denotes any semiconducting material including, for example, Si, Ge, SiGe, SiC, SiGeC, InAs, GaAs, InP or other like III/V compound semiconductors. Multilayers of these semiconductor materials can also be used as the semiconductor material of the handle substrate and the semiconductor layer. In one embodiment, the handle substrate and the semiconductor layer are both comprised of Si.

The handle substrate and the semiconductor layer may have the same or different crystal orientation. For example, the crystal orientation of the handle substrate and/or the semiconductor layer may be {100}, {110}, or {111}. Other crystallographic orientations besides those specifically mentioned can also be used in the present disclosure. The handle substrate and/or the semiconductor layer of the SOI substrate may be a single crystalline semiconductor material, a polycrystalline material, or an amorphous material. Typically, at least the semiconductor layer is a single crystalline semiconductor material.

The buried insulating layer of the SOI substrate may be a crystalline or non-crystalline oxide or nitride. In one embodiment, the buried insulating layer is an oxide. The buried insulating layer may be continuous or it may be discontinuous. When a discontinuous buried insulating region is present, the insulating region exists as an isolated island that is surrounded by semiconductor material.

The SOI substrate may be formed utilizing standard processes including for example, SIMOX (separation by ion implantation of oxygen) or layer transfer. When a layer transfer process is employed, an optional thinning step may follow the bonding of two semiconductor wafers together. The optional thinning step reduces the thickness of the semiconductor layer to a layer having a thickness that is more desirable.

The thickness of the semiconductor layer of the SOI substrate is typically from 100 Å to 1000 Å, with a thickness from 500 Å to 700 Å being more typical. If the thickness of the semiconductor layer is not within one of the above mentioned ranges, a thinning step such as, for example, planarization or etching can be used to reduce the thickness of the semiconductor layer to a value within one of the ranges mentioned above.

The buried insulating layer of the SOI substrate typically has a thickness from 10 Å to 2000 Å, with a thickness from 1000 Å to 1500 Å being more typical. The thickness of the handle substrate of the SOI substrate is inconsequential to the present disclosure.

In some other embodiments, hybrid semiconductor substrates which have surface regions of different crystallographic orientations can be employed as semiconductor substrate 10. When a hybrid substrate is employed, an nFET is typically formed on a (100) crystal surface, while a pFET is typically formed on a (110) crystal plane. The hybrid substrate can be formed by techniques that are well known in the art. See, for example, U.S. Pat. No. 7,329,923, U.S. Publication No. 2005/0116290, dated Jun. 2, 2005 and U.S. Pat. No. 7,023,055, the entire contents of each are incorporated herein by reference.

In some embodiments, at least one isolation region (not shown) can be formed into the semiconductor substrate 10 at this point of the present disclosure to isolate one active device region from another active device region. For example, an isolation region may be formed into the semiconductor substrate 10 to isolate a pFET device region (not shown) from an nFET device region (not shown). In one embodiment of the present disclosure, the at least one isolation region is a field oxide isolation that can be formed utilizing a process referred to as a local oxidation of silicon process. In another embodiment, the at least one isolation region is a trench isolation region. When a trench isolation is employed as the at least one isolation region, the trench isolation region can be formed utilizing any conventional trench isolation process which is well known to those skilled in the art. For example, the trench isolation region can be formed by lithography, etching a trench into the substrate, filling the trench with a trench dielectric material such as, for example, an oxide, and planarization. In some embodiments, a liner can be formed prior to trench fill. In other embodiments, a densification process can be performed.

Referring to FIG. 2, there is shown the semiconductor substrate 10 of FIG. 1 after forming at least one patterned gate structure 16 on an upper surface of the semiconductor substrate 10. As shown, the at least one patterned gate structure 16 includes, from bottom to top, a dielectric material layer portion 12 and a conductive material layer portion 14.

The dielectric material layer portion 12 employed in the present disclosure can include any insulating material such as for example, an oxide, a nitride, an oxynitride or a multilayered stack thereof. In one embodiment, the dielectric material layer portion 12 can include a semiconductor oxide, a semiconductor nitride or a semiconductor oxynitride. In another embodiment, the dielectric material portion 12 can include a dielectric metal oxide or mixed metal oxide having a dielectric constant that is greater than the dielectric constant of silicon oxide, i.e., 3.9. Typically, the dielectric material that can be employed as the dielectric material layer portion 12 has a dielectric constant greater than 4.0, with a dielectric constant of greater than 8.0 being more typical. Such dielectric materials are referred to herein as high k dielectrics. Exemplary high k dielectrics include, but are not limited to, HfO₂, ZrO₂, La₂O₃, Al₂O₃, TiO₂, SrTiO₃, LaAlO₃, Y₂O₃, HfOₓN_{y}, ZrOₓN_{y}, La₂OₓN_{y}, Al₂OₓN_{y}, TiOₓN_{y}, SrTiOₓN_{y}, LaAlOₓN_{y}, Y₂OₓN_{y}, SiON, SiNₓ, a silicate thereof, and an alloy thereof. Multilayered stacks of these high k materials can also be employed as the dielectric material layer portion 12. Each value of x is independently from 0.5 to 3 and each value of y is independently from 0 to 2.

The thickness of the dielectric material layer portion 12 may vary depending on the technique used to form the same. Typically, the dielectric material layer portion 12 that can be employed has a thickness from 1 nm to 20 nm, with a thickness from 2 nm to 10 nm being more typical.

The dielectric material layer portion 12 can be formed by first depositing a blanket layer of dielectric material on an upper surface of semiconductor substrate 10. The blanket layer of dielectric material used in forming the dielectric material layer portion 12 can be formed by methods well known in the art. In one embodiment, the blanket layer of the dielectric material can be formed by a deposition process such as, for example, chemical vapor deposition (CVD), plasma enhanced chemical vapor deposition (PECVD), physical vapor deposition (PVD), molecular beam deposition (MBD), pulsed laser deposition (PLD), liquid source misted chemical deposition (LSMCD), and atomic layer deposition (ALD). In another embodiment, the blanket layer of dielectric material can be formed by a thermal process including, for example, thermal oxidation and/or thermal nitridation. In yet another embodiment, any combination of the above mentioned techniques, e.g., thermal oxidation and CVD, can be used in forming the blanket layer of dielectric material.

After forming the blanket layer of dielectric material, a blanket layer of a conductive material is formed atop the blanket layer of dielectric material. The blanket layer of conductive material includes any conductive material including, but not limited to, polycrystalline silicon, polycrystalline silicon germanium, an elemental metal (e.g., tungsten, titanium, tantalum, aluminum, nickel, ruthenium, palladium and platinum), an alloy of at least one elemental metal, an elemental metal nitride (e.g., tungsten nitride, aluminum nitride, and titanium nitride), an elemental metal silicide (e.g., tungsten silicide, nickel silicide, and titanium silicide) and multilayered combinations thereof. In one embodiment, the blanket layer of conductive material can be comprised of an nFET metal gate. In another embodiment, the blanket layer of conductive material can be comprised of a pFET metal gate. In a further embodiment, the conductive material can be comprised of polycrystalline silicon. The polysilicon conductive material can be used alone, or in conjunction with another conductive material such as, for example, a metal conductive material and/or a metal silicide material.

The blanket layer of conductive material can be formed utilizing a conventional deposition process including, for example, chemical vapor deposition (CVD), plasma enhanced chemical vapor deposition (PECVD), physical vapor deposition (PVD), sputtering, atomic layer deposition (ALD) and other like deposition processes. When Si-containing materials are used as the conductive material, the Si-containing materials can be doped within an appropriate impurity by utilizing either an in-situ doping deposition process or by utilizing deposition, followed by a step such as ion implantation or gas phase doping in which the appropriate impurity is introduced into the Si-containing material. When a metal silicide is formed, a conventional silicidation process is employed. The as-deposited blanket layer conductive material typically has a thickness from 1 nm to 100 nm, with a thickness from 3 nm to 30 nm being even more typical.

In some embodiments (not shown) an optional hard mask can be formed atop the surface of the blanket layer of conductive material. When present, the optional hard mask can be comprised of an oxide, nitride or oxynitride, with oxides of silicon and/or nitrides of silicon being highly typical. The hard mask, if present, can be formed utilizing a conventional deposition process including, but not limited to, CVD, PECVD, ALD, and chemical solution deposition. Alternatively, the hard mask can be formed by a thermal oxidation and/or nitridation process.

The thickness of the optional hard mask, if present, may vary depending on the material of the hard mask, as well as the processing technique used to form the same. Typically, the optional hard mask has a thickness from 50 Å to 1000 Å, with a thickness from 100 Å to 500 Å being more typical.

Following deposition of the blanket layers of conductive material and dielectric material, the blanket layers of the conductive material and the dielectric material can be patterned by lithography and etching into the conductive material layer portion 14 and the dielectric material layer portion 12, respectively. When the hard mask is present, the hard mask is also patterned at this point of the present disclosure forming a hard mask cap (not shown) atop the conductive material layer portion 14. For clarity, the following discussion omits the embodiment in which a hard mask cap is located atop the conductive material layer portion 14.

The lithographic step used in patterning the blanket layers of conductive material and the dielectric material includes first applying a photoresist (positive-tone, negative-tone or a combination of both a positive-tone and a negative-tone) atop the blanket layer of conductive material. The photoresist can be applied atop the blanket layer of conductive material utilizing any conventional deposition process including, for example, spin-coating. Following the application of the photoresist to the blanket layer of conductive material, the photoresist is exposed to a desired pattern of radiation and thereafter the exposed resist is developed utilizing a conventional resist developer. The pattern within the developed photoresist is then transferred into the underlying blanket layers utilizing one or more etching steps, including dry etching and/or wet etching. When dry etching is used to transfer the pattern into the underlying blanket layers, one of reactive ion etching, ion bean etching, plasma etching and laser ablation can be used. When wet etching is used, a chemical etchant that selectively removes exposed portions of the conductive material can be employed. The transfer of the pattern may first be into the blanket of conductive material, and then into the blanket layer of dielectric material. The etching typically stops on an upper surface of the semiconductor substrate 10. The resist can be removed after the pattern transfer into one, or all, of the blanket layers by utilizing a conventional resist removal step such as, for example, ashing.

Referring to FIG. 3, there is illustrated the structure of FIG. 2 after forming a patterned masking material layer 18 on areas of the upper surface of the semiconductor substrate 10 and on sidewalls and atop the patterned gate region 16. The patterned masking material layer 18 comprises any masking material that is dissimilar to that of substrate 10 and thus provides a different incubation time for subsequent epitaxial growth of a semiconductor material than the incubation time for subsequent epitaxial growth of the same semiconductor material on the substrate. Specifically, the patterned masking material layer 18 comprises any masking material that has a slower nucleation rate for subsequent semiconductor growth than exposed areas of the semiconductor substrate which do not include the patterned masking material layer 18.

The patterned masking material layer 18 can be comprised of a semiconductor, a dielectric, a metal or a multilayered combination thereof. In one embodiment, the patterned masking material is comprised of a semiconductor masking material. The semiconductor masking material may include any of the semiconductor materials mentioned above for semiconductor substrate 10. In some embodiments, the semiconductor masking material is a crystalline semiconductor. In other embodiments, the semiconductor masking material is a polycrystalline semiconductor. In yet another embodiment, the semiconductor masking material is an amorphous (i.e., lacks a specific crystal structure) semiconductor.

In one embodiment, the semiconductor masking material used in forming the patterned masking material layer 18 is different in terms of its composition than the semiconductor substrate 10. For example, and when silicon is employed as the semiconductor substrate 10, the masking material that can be used as the patterned masking material layer 18 can comprise Ge.

In another embodiment, the masking material used in forming the patterned masking material layer 18 comprises the same semiconductor material as that of the substrate. In such an embodiment, the semiconductor material used as the patterned masking material layer 18 is modified to provide the slower nucleation rate mentioned above. In this embodiment, the modification of the semiconductor masking material can be achieved after blanket deposition of the semiconductor masking material utilizing plasma exposure, ion implantation, chemical exposure or photochemical exposure. The aforementioned techniques can also be employed with any of the other types of masking materials mentioned above.

When a dielectric masking material is employed as the patterned masking material layer 18, the dielectric masking material can be an oxide (including a semiconductor oxide), a nitride (including a semiconductor nitride) or an oxynitride (including a semiconductor oxynitride). In some embodiments, the dielectric masking material can be comprised of a photoresist material.

When a metal masking material is employed as the patterned masking material layer 18, the metal masking material can be an elemental metal which is compatible with the reactor thermal environment such as, for example, W, Ti, Ta, Ru, Pt, and Pd, or an elemental metal alloy including at least two of the aforementioned elemental metals.

The patterned masking material layer 18 can be formed by first forming a blanket layer of one of the aforementioned masking materials on the surface of the structure shown in FIG. 2, and then patterning the blanket layer of masking material by lithography and etching. An optional modification, i.e., treatment, step as mentioned above can be performed after forming the blanket layer of masking material.

The forming of the blanket layer of masking material on the structure includes any deposition process such as, but not limited to, chemical vapor deposition, plasma enhanced chemical vapor deposition, chemical solution deposition, and physical vapor deposition.

The optional modification step that can be used includes plasma exposure, ion implantation, chemical exposure or photochemical exposure.

When a plasma exposure process is performed, the blanket layer of masking material can be exposed to any type of plasma including, but not limited to, an oxygen plasma and/or a nitrogen plasma. The plasma is generated using conditions and apparatuses that are well known to those skilled in the art. The plasma exposure may modify only an upper surface of the blanket layer of masking material, or it may modify the entire thickness of the blanket layer of masking material.

When ion implantation is performed, various types of ions such as, for example, ions from Group IIIA of the Periodic Table of Elements (i.e., one of B, Al, Ga, In and Tl), ions from Group IVA of the Periodic Table of Elements (i.e., C, Si, Ge and Sn) and ions from Group VA of the Periodic Table of Elements (i.e., N, P, As, Sb and Bi) can be implanted into the blanket layer of masking material. The ions can be implanted utilizing conditions that are well known to those skilled in the art, and the concentration of the ions that are implanted into the blanket masking material layer must be of a sufficient quantity to provide the masking material with a slower nucleation rate for subsequent epitaxial growth of a semiconductor material as compared to the exposed surface of the substrate that does not include the patterned masking material layer 18.

When a chemical exposure is performed, the blanket layer of masking material can be treated with any reactant, e.g., oxidizing agent or reducing agent, that can modify the masking material to have the slower nucleation rate for subsequent epitaxial growth of a semiconductor material as compared to the exposed surface of the substrate that does not include the patterned masking material layer 18. Examples of oxidizing agents include, but are not limited to, hydrogen peroxide and other inorganic peroxides; nitric acid and nitrates; chlorite, chlorate, perchlorates and other analogous halogen compounds; and fluorine and other halogen. Examples of reducing agents that can be employed include, but are not limited to, lithium aluminum fluoride; sodium borohydride; compounds containing Sn²⁺ such as tin(II) chloride; hydrazine; oxalic acid; formic acid; ascorbic acid; and phosphites, hypoposphites and phosphorus acid.

When photochemical exposure is employed, the blanket layer of making material can be exposed to an exposure light source of G-line, I-line (365 nm), DUV (248 nm, 193 nm, 157 nm, 126 nm), Extreme UV (13.4 nm), an electron beam, or an ion beam.

Following deposition of the blanket layer of masking material and the optional modification step, the blanket layer of masking material is patterned by lithography and etching. The lithographic step used in patterning the blanket layer of masking material includes first applying a photoresist (positive-tone, negative-tone or a combination of both a positive-tone and a negative-tone) atop the blanket layer of masking material. The photoresist can be applied atop the blanket layer of conductive material utilizing any conventional deposition process including, for example, spin-coating. Following the application of the photoresist to the blanket layer of masking material, the photoresist is exposed to a desired pattern of radiation and thereafter the exposed resist is developed utilizing a conventional resist developer. The pattern within the developed photoresist is then transferred into the underlying blanket layer utilizing one or more etching steps, including dry etching and/or wet etching. When dry etching is used to transfer the pattern into the underlying blanket layer, one of reactive ion etching, ion bean etching, plasma etching and laser ablation can be used. When wet etching is used, a chemical etchant that selectively removes exposed portions of the masking material can be employed. The etching typically stops on an upper surface of the semiconductor substrate 10. The resist can be removed after the pattern transfer utilizing a conventional resist removal step such as, for example, ashing.

At this point of the present disclosure, trenches (represented by phantom dotted lines 50) can be etched into the exposed surfaces of the semiconductor substrate 10 utilizing the patterned masking layer 18 and the patterned gate structure 16 as etch masks. In one embodiment, the trenches can have substantially straight sidewalls (as shown in FIG. 3 by the phantom dotted lines). In another embodiment, the trenches have slanted sidewalls. By “slanted wall profile” it is meant the surface of the wall created is oriented at a particular angle (relative to the top surface of substrate 10) dictated by the crystallographic planes particular to crystallographic etchants and etch rate chosen. The ‘slant’ of the sidewall may be positive sloped, negative sloped, or a combination of both.

Referring to FIG. 4, there is illustrated the structure of FIG. 3 after epitaxial growth of semiconductor material 20 on areas of the semiconductor substrate 10 that are exposed. “Epitaxial growth” as used herein denotes the growth of a semiconductor material on a surface of a semiconductor substrate, in which the semiconductor material being grown has the same crystalline characteristics and orientation as the surface of the semiconductor substrate. When the chemical reactants are controlled and the system parameters set correctly, the depositing atoms arrive at exposed surface areas of substrate 10 with sufficient energy to move around on the surface and orient themselves to the crystal arrangement of the atoms of the deposition surface. Thus, an epitaxial film deposited on a {100} crystal surface will take on a {100} orientation.

The semiconductor material 20 that is formed by epitaxial growth comprises any semiconductor that can be undoped or in-situ doped with at least one dopant. Examples of semiconductor materials that can be formed include, but are not limited to, silicon (Si), silicon germanium (SiGe), carbon-doped silicon (Si:C), carbon doped silicon germanium (SiGe:C), boron doped silicon (Si:B), phosphorus doped silicon (Si:P), arsenic doped silicon (Si:As), doped Si:C, GeSn, doped GeSn or SiGeSn. In some embodiments, the semiconductor material 20 could be a III/V or II/VI compound semiconductor.

The epitaxial growth includes providing at least one semiconductor material precursor such as a silane, a germane, and a stannous compound, and then depositing the at least one semiconductor material precursor on the exposed areas of the substrate 10. In some cases, at least one dopant can be used in conjunction with a semiconductor precursor to provide an in-situ doped semiconductor material.

The epitaxial growth without or without the dopant can be performed at various temperatures. In some embodiments, no etchant gas such as, for example, HCl, is employed during the epitaxial growth process. In one embodiment, the epitaxial growth is performed at a temperature of about 500° C. or less. In another embodiment, the epitaxial growth can be performed at a temperature of about 700° C., without the need of utilizing an etchant gas. In yet another embodiment, the epitaxial growth is performed at a temperature in the range between 500° C. and 700 ° C.

The term “in-situ doped” means that the dopant is introduced during the epitaxial growth process that provides the semiconductor material 20. In one embodiment, the in-situ doped semiconductor material is doped with a first conductivity type dopant during the epitaxial growth process. As used herein, the term “conductivity type” denotes a dopant region being p-type or n-type. As used herein, “p-type” refers to the addition of impurities to an intrinsic semiconductor that creates deficiencies of valence electrons. In a silicon-containing substrate, examples of n-type dopants, i.e., impurities, include but are not limited to boron, aluminum, gallium and indium. As used herein, “n-type” refers to the addition of impurities that contributes free electrons to an intrinsic semiconductor. In a silicon containing substrate examples of n-type dopants, i.e., impurities, include but are not limited to, antimony, arsenic and phosphorous.

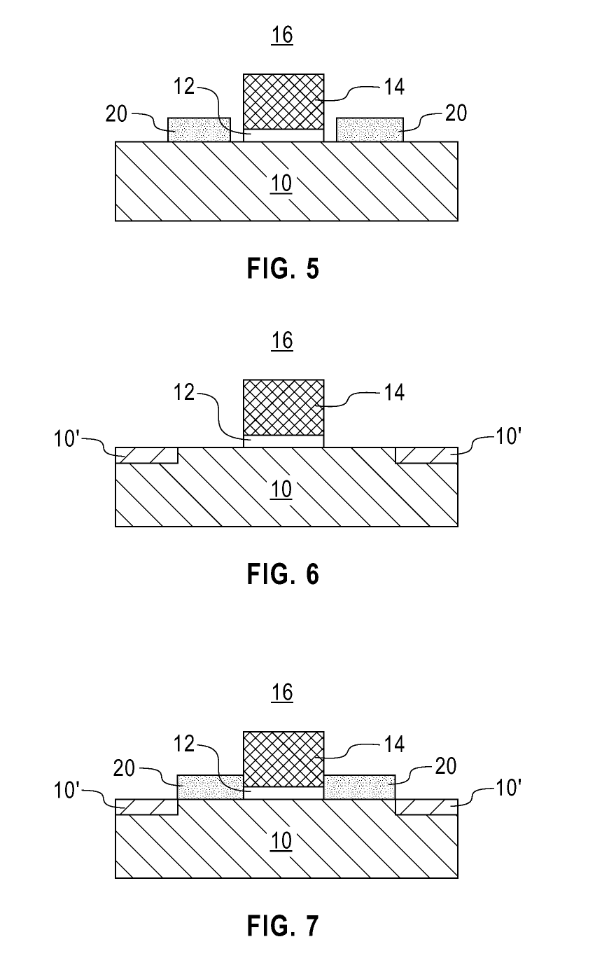

In some embodiments, the semiconductor material 20 can also be formed atop the patterned masking material layer 18 (not shown in the drawings). In this embodiment, the semiconductor material 20 that is formed atop the patterned masking material is a discontinuous layer due to the slower nucleation rate associated with the patterned masking material layer 18 compared to the exposed areas of the substrate 10. In such an embodiment, the discontinuous semiconductor layer 20 that forms atop the patterned masking material layer 18 is removed during removal of the patterned masking material layer 18 which is described herein below and in FIG. 5.

Referring to FIG. 5, there is illustrated the structure of FIG. 4 after selectively etching the masking layer 18, relative to semiconductor material 20, conductive material layer portion 14 and the semiconductor material of substrate 10, from the structure. The selective etching process can include dry etching, wet chemical etching or a combination of wet chemical etching and dry etching. When a dry etching process is employed in selectively removing the patterned masking material layer 18, the dry etching process can include, for example, reactive ion etching, plasma etching, and ion beam etching. In one embodiment, hydrogen peroxide or a mixture of NH₄OH:H₂O₂:H₂O can be used as an etchant to remove the patterned masking material layer 18 from the structure

Reference is now made to FIGS. 6-7 which illustrate another embodiment of the present disclosure which can be used to selectively grown a semiconductor material by incubation time engineering. In this embodiment, a surface treatment step is performed to alter selected areas of a semiconductor substrate so that the altered surface region has a longer nucleation time, i.e., incubation time, for epitaxial growth of a semiconductor material as compared to the non-altered regions of the substrate. Specifically, FIG. 6 depicts the structure of FIG. 2 after performing a surface treatment which forms modified surface regions 10′ within the initial semiconductor substrate 10. In some embodiments, the structure shown in FIG. 6 can be first formed by performing the surface modification to the structure shown in FIG. 1 and then forming the patterned gate structure 16. In another embodiment, the structure shown in FIG. 6 can be first formed by providing the patterned gate structure 16 and then performing the surface modification to the structure shown in FIG. 2. Trenches can be formed into the structure shown in FIG. 6 similar to those shown by the photon dotted lines in FIG. 3.

The modified surface regions 10′ that are formed in this embodiment serve as the patterned masking material layer mentioned in the embodiment described above. The modified surface regions 10′ can be formed utilizing plasma exposure, ion implantation, chemical exposure or photochemical exposure. By modifying selected areas of the semiconductor substrate 10, the modified areas have a slower nucleation rate for semiconductor growth than the areas of the semiconductor substrate 10 that are not modified. The modified surface regions 10′ of the semiconductor substrate 10 are different in terms of their chemical properties, dopant type, dopant concentration, hardness, etc. than the unmodified areas of the substrate.

When a plasma exposure process is performed, a mask is first formed on selected areas of the substrate and then the surface of the semiconductor substrate 10 not protected by the mask can be exposed to any type of plasma including, but not limited to, an oxygen plasma and/or a nitrogen plasma. The plasma is generated using conditions and apparatus that are well known to those skilled in the art. Following plasma exposure, the mask can be removed utilizing techniques well known to those skilled in the art.

When ion implantation is performed, a mask is first formed on selected areas of the substrate and various type of ions such as, for example, ions from Group IIIA of the Periodic Table of Elements (i.e., one of B, Al, Ga, In and Tl), ions from Group IVA of the Periodic Table of Elements (i.e., C, Si, Ge and Sn) and ions from Group VA of the Periodic Table of Elements (i.e., N, P, As, Sb and Bi) can be implanted into the non-protected areas of the substrate 10. The ions can be implanted utilizing conditions that are well known to those skilled in the art, and the concentration of the ions that are implanted into the non-protected areas of the substrate must be of a sufficient quantity to provide the modified surface region with a slower nucleation rate for subsequent epitaxial growth of a semiconductor material as compared to the exposed surface of the substrate that does not include the modified surface region. Following ion implantation, the mask can be removed utilizing techniques well known to those skilled in the art.

When a chemical exposure is performed, the a mask is first provided and the non-protected areas of the substrate 10 can be treated with any reactant, e.g., oxidizing agent or reducing agent, that can modify the exposed surface region of substrate 10 to have the slower nucleation rate for subsequent epitaxial growth of a semiconductor material as compared to the non-chemical exposed surface of the substrate. Examples of oxidizing agents include, but are not limited to, hydrogen peroxide and other inorganic peroxides; nitric acid and nitrates; chlorite, chlorate, perchlorates and other analogous halogen compounds; and fluorine and other halogen. Examples of reducing agents that can be employed include, but are not limited to, lithium aluminum fluoride; sodium borohydride; compounds containing Sn²⁺ such as tin(II) chloride; hydrazine; oxalic acid; formic acid; ascorbic acid; and phosphites, hypoposphites and phosphorus acid. Following chemical exposure, the mask can be removed utilizing techniques well known to those skilled in the art.

When photochemical exposure is employed, a mask is first formed and then the non-protected areas of the substrate 10 can be exposed to an exposure light source of G-line, I-line (365 nm), DUV (248 nm, 193 nm, 157 nm, 126 nm), Extreme UV (13.4 nm), an electron beam, or an ion beam.

Referring now to FIG. 7, there is illustrated the structure of FIG. 6 after selective epitaxial growth of a semiconductor material 20 on areas of the semiconductor substrate not including the modified surface regions 10′. The selective epitaxial growth and materials used in this embodiment of the present disclosure are the same as those described above in the embodiment of the present disclosure that is depicted in FIGS. 1-5.

In one embodiment, the semiconductor material 20 that is epitaxially grown in the present disclosure can be entirely embedded within the substrate 10. In another embodiment, the semiconductor material 20 that is epitaxially grown in the present disclosure can have a portion that is embedded in the substrate 10, and another portion that extends above the upper surface of substrate 10. In yet a further embodiment, the semiconductor material 20 that is epitaxially grown in the present disclosure can be entirely located on an upper surface of a non-recessed area of substrate 10.

While the present disclosure has been particularly shown and described with respect to various embodiments thereof, it will be understood by those skilled in the art that the foregoing and other changes in forms and details may be made without departing from the spirit and scope of the present disclosure. It is therefore intended that the present disclosure not be limited to the exact forms and details described and illustrated, but fall within the scope of the appended claims.

What is claimed is:

1. A method of forming a semiconductor material on selected areas of a semiconductor substrate, said method comprising:
forming a patterned masking material layer on selected areas of a semiconductor substrate, while leaving other selected areas of the semiconductor substrate exposed, wherein said patterned masking material layer has a slower nucleation rate for semiconductor growth than said exposed areas of the semiconductor substrate;
epitaxially growing a semiconductor material on the exposed areas of the semiconductor substrate not including said patterned masking material layer; and
removing the patterned masking material layer selective to the epitaxially grown semiconductor material.

2. The method of claim 1, wherein said forming the patterned masking material layer comprises deposition of a blanket layer of masking material, lithography and etching.

3. The method of claim 2, wherein said masking material is a semiconductor, a dielectric, a metal or a multilayered layer stack thereof.

4. The method of claim 2, wherein said semiconductor substrate comprises silicon and said masking material comprises germanium.

5. The method of claim 2, wherein said masking material is a crystalline semiconductor.

6. The method of claim 2, wherein said masking material is a polycrystalline or an amorphous semiconductor.

7. The method of claim 2, wherein said blanket layer of masking material is modified prior to lithography and etching, said modifying comprising plasma exposure, ion implantation, chemical exposure or photochemical exposure.

8. The method of claim 1, wherein said epitaxially growing is performed at a temperature of about 500° C. or less.

9. The method of claim 1, wherein said epitaxially growing is performed at a temperature of about 650° C. or greater.

10. The method of claim 1, wherein said semiconductor material comprises silicon (Si), silicon germanium (SiGe), carbon-doped silicon (Si:C), carbon doped silicon germanium (SiGe:C), boron doped silicon (Si:B), phosphorus doped silicon (Si:P), arsenic doped silicon (Si:As), doped Si:C, GeSn, doped GeSn or SiGeSn.

11. The method of claim 1, wherein during said epitaxially growing a discontinuous semiconductor material forms atop the patterned masking layer, said discontinuous semiconductor material is subsequently removed during said removing the patterned masking material layer.

12. The method of claim 1, further comprising etching the exposed areas of the substrate prior to epitaxially growing said semiconductor material.

13. The method of claim 1, wherein said epitaxially growing is performed in the absence of any etchant gas.

14. A method of forming a semiconductor material on selected areas of a semiconductor substrate, said method comprising:
forming a modified surface region in selected areas of a semiconductor substrate, while leaving other selected areas of the semiconductor substrate non-modified, wherein the modified surface region has a slower nucleation rate for semiconductor growth than the non-modified areas of the semiconductor substrate; and
epitaxially growing a semiconductor material on the non-modified areas of the semiconductor substrate not including the modified surface region.

15. The method of claim 14, wherein said modified surface region is formed by plasma exposure, ion implantation, chemical exposure or photochemical exposure.

16. The method of claim 14, wherein said epitaxially growing is performed at a temperature of about 500° C. or less.

17. The method of claim 14, wherein said epitaxially growing is performed at a temperature of about 650° C. or greater.

18. The method of claim 14, wherein said semiconductor material comprises silicon (Si), silicon germanium (SiGe), carbon-doped silicon (Si:C), carbon doped silicon germanium (SiGe:C), boron doped silicon (Si:B), phosphorus doped silicon (Si:P), arsenic doped silicon (Si:As), doped Si:C, GeSn, doped GeSn or SiGeSn.

19. The method of claim 14, further comprising etching the exposed areas of the substrate prior to epitaxially growing said semiconductor material.

20. The method of claim 14, wherein said epitaxially growing is performed in the absence of any etchant gas.
